(19) United States
(12) Patent Application Publication
(10) Pub. No.: US 2026/0255710 A1
(43) Pub. Date: Aug. 27, 2026

(54) SEMICONDUCTOR DIE PROTECTING PACKAGES

(71) Applicant: Meta Platforms Technologies, LLC, Menlo Park, CA (US)

(72) Inventor: Rajendra D Pendse, Fremont, CA (US)

(21) Appl. No.: 19/547,514

(22) Filed: Feb. 23, 2026

Related U.S. Application Data
(60) Provisional application No. 63/763,182, filed on Feb. 25, 2025.

(51) Int. Cl. H10F 39/00

(52) U.S. Cl. CPC H10F 39/804; H10F 39/8063; H10F 39/811; H10F 39/024

(57) ABSTRACT

An image sensor includes a substrate, a semiconductor die, a mold material, and a micro-dam. The semiconductor die is connected atop the substrate by a wire bond. The semiconductor die includes a two-dimensional pixel array on a top surface of the semiconductor die. The mold material is deposited on the top surface of the semiconductor die to a mold height that exceeds a height of the wire bond. The micro-dam is disposed on the top surface of the semiconductor die between the two-dimensional pixel array and the mold material. The micro-dam is configured to prevent the mold material from reaching a semiconductor feature zone of the semiconductor die.

### CROSS-REFERENCE TO RELATED APPLICATIONS

This application claims priority to U.S. provisional Application No. 63/763,182 filed February 25, 2025, which is hereby incorporated by reference.

### TECHNICAL FIELD

This disclosure relates generally to semiconductors, and in particular to fabrication of packages that include semiconductor dies.

### BACKGROUND INFORMATION

The fabrication of electronic packages, such as image sensors, sensors, and displays often suffer losses ranging from 5% to 20%. These losses are frequently driven by mechanical damage during the assembly and fabrication process. For example, damage to the semiconductor die can occur during wire-bonding stages or during a molding process. Furthermore, contamination of portions of the sensor die may be sustained during the packaging process that negatively affects the sensing or pixel function of the electronics included in the semiconductor die.

### BRIEF DESCRIPTION OF THE DRAWINGS

Non-limiting and non-exhaustive embodiments of the invention are described with reference to the following figures, wherein like reference numerals refer to like parts throughout the various views unless otherwise specified.

FIG. 1 illustrates a head-mounted device that includes one or more cameras that may be exposed to an external environment, in accordance with aspects of the disclosure.

FIGS. 2A and 2B illustrate an electronic package before and after a molding process.

FIG. 3A illustrates an example electronic structure, in accordance with aspects of the disclosure.

FIG. 3B illustrates an example image sensor electronic device that includes microlenses for focusing image light to an image pixel array, in accordance with aspects of the disclosure.

FIG. 4A illustrates an electronic structure that includes a micro-dam disposed on the top surface of a semiconductor die, in accordance with aspects of the disclosure.

FIG. 4B illustrates an overhead view of a portion of example electronic structure that includes a micro-dam, in accordance with aspects of the disclosure.

FIG. 5A illustrates an electronic structure that includes a sacrificial lid relief structure disposed on a micro-dam, in accordance with aspects of the disclosure.

FIG. 5B illustrates an overhead view of a portion of an example electronic structure that includes a sacrificial lid covering a semiconductor feature zone, in accordance with aspects of the disclosure.

FIG. 6A illustrates an electronic structure that includes a mold material deposited on the top surface of semiconductor die, in accordance with aspects of the disclosure.

FIG. 6B illustrates an overhead view of a portion of an example electronic structure that includes a molding material disposed around a sacrificial lid, in accordance with aspects of the disclosure.

FIG. 7 illustrates an electronic structure after a sacrificial lid has been removed to uncover a semiconductor feature zone, in accordance with aspects of the disclosure.

FIG. 8 illustrates an example process of fabricating a device where the fabrication process includes a sacrificial lid, in accordance with aspects of the disclosure.

FIG. 9A illustrates an example electronic structure, in accordance with aspects of the disclosure.

FIG. 9B illustrates an example image sensor electronic device that includes microlenses for focusing image light to an image pixel array, in accordance with aspects of the disclosure.

FIG. 10A illustrates an electronic structure that includes a micro-dam disposed on the top surface of a semiconductor die, in accordance with aspects of the disclosure.

FIG. 10B illustrates an overhead view of a portion of an example electronic structure that includes a micro-dam, in accordance with aspects of the disclosure.

FIG. 11A illustrates an electronic structure that includes a mold material disposed next to a micro-dam, in accordance with aspects of the disclosure.

FIG. 11B illustrates an overhead view of a portion of an example electronic structure that includes a micro-dam arranged to prevent a mold material from reaching a semiconductor features zone of a semiconductor die, in accordance with aspects of the disclosure.

FIG. 12A illustrates an example electronic structure, in accordance with aspects of the disclosure.

FIG. 12B illustrates an example image sensor electronic device that includes microlenses for focusing image light to an image pixel array, in accordance with aspects of the disclosure.

FIG. 13A illustrates an electronic structure that includes a micro-dam disposed on the top surface of a semiconductor die, in accordance with aspects of the disclosure.

FIG. 13B illustrates an overhead view of a portion of an example electronic structure that includes a micro-dam, in accordance with aspects of the disclosure.

FIG. 14A illustrates an electronic structure that includes a mold material disposed next to a micro-dam, in accordance with aspects of the disclosure.

FIG. 14B illustrates an overhead view of a portion of an example electronic structure that includes a micro-dam arranged to prevent a mold material from reaching a semiconductor features zone of a semiconductor die, in accordance with aspects of the disclosure.

### DETAILED DESCRIPTION

Embodiments of semiconductor die protection packages are described herein. In the following description, numerous specific details are set forth to provide a thorough understanding of the embodiments. One skilled in the relevant art will recognize, however, that the techniques described herein can be practiced without one or more of the specific details, or with other methods, components, materials, etc. In other instances, well-known structures, materials, or operations are not shown or described in detail to avoid obscuring certain aspects.

Reference throughout this specification to “one embodiment” or “an embodiment” means that a particular feature, structure, or characteristic described in connection with the embodiment is included in at least one embodiment of the present invention. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

In some implementations of the disclosure, the term “near-eye” may be defined as including an element that is configured to be placed within 50 mm of an eye of a user while a near-eye device is being utilized. Therefore, a “near-eye optical element” or a “near-eye system” would include one or more elements configured to be placed within 50 mm of the eye of the user.

In aspects of this disclosure, visible light may be defined as having a wavelength range of approximately 380 nm – 700 nm. Non-visible light may be defined as light having wavelengths that are outside the visible light range, such as ultraviolet light and infrared light. Infrared light having a wavelength range of approximately 700 nm – 1 mm includes near-infrared light. In aspects of this disclosure, near-infrared light may be defined as having a wavelength range of approximately 700 nm - 1.6 µm.

In aspects of this disclosure, the term “transparent” may be defined as having greater than 90% transmission of light. In some aspects, the term “transparent” may be defined as a material having greater than 90% transmission of visible light.

Embodiments of the invention may include or be implemented in conjunction with an artificial reality system. Artificial reality is a form of reality that has been adjusted in some manner before presentation to a user, which may include, e.g., a virtual reality (VR), an augmented reality (AR), a mixed reality (MR), a hybrid reality, or some combination and/or derivatives thereof. Artificial reality content may include completely generated content or generated content combined with captured (e.g., real-world) content. The artificial reality content may include video, audio, haptic feedback, or some combination thereof, and any of which may be presented in a single channel or in multiple channels (such as stereo video that produces a three-dimensional effect to the viewer). Additionally, in some embodiments, artificial reality may also be associated with applications, products, accessories, services, or some combination thereof, that are used to, e.g., create content in an artificial reality and/or are otherwise used in (e.g., perform activities in) an artificial reality. The artificial reality system that provides the artificial reality content may be implemented on various platforms, including a head-mounted display (HMD) connected to a host computer system, a standalone HMD, a mobile device or computing system, or any other hardware platform capable of providing artificial reality content to one or more viewers.

The traditional packaging process for image sensor chips involves cavity molding to expose the pixel array. For example, sensor chips with pixel arrays or other sensitive features on the die surface are packaged using wire bonding and a cavity molding process to expose the die surface. This cavity molding inevitably causes contamination and mechanical damage to the pixel array resulting in large yield losses (e.g., typically in 5-20% range).

Wafer-level packaging is a process in integrated circuit manufacturing in which packaging components may be attached to an integrated circuit (IC) before the wafer – on which the IC is fabricated – is diced. For example, the top and bottom layers of the packaging and the solder bumps may be attached to the integrated circuits while they are still in the wafer. This process differs from a process like substrate level packaging in which the wafer may be sliced into individual circuits (e.g., dice) before the packaging components are attached.

The present disclosure is generally directed to a novel structure/process that creates a relief structure to protect the die surface during cavity molding and other process steps, thereby preventing contamination and damage. For example, a relief structure such as a sacrificial lid may be configured to temporarily cover one or more features of a semiconductor device during fabrication of an electronics package. Additionally, the semiconductor device may be subjected to a cavity molding process with the relief structure covering the one or more features. Also, at least part of the relief structure may be removed to expose the one or more features. This novel structure/process may reduce yield losses.

The disclosed systems, structures, and methods are applicable to chips for image sensors, micro-electro-mechanical systems (MEMS) sensors, or displays which have pixel arrays or other sensitive features on the die surface that need to be exposed yet free from contamination or mechanical damage. In some implementations (e.g., substrate-level or wafer-level packaging process) the relief structure may be implemented by attaching a sacrificial lid over the pixel array region prior to the packaging process and then removing the lid (e.g., by chemical etching, wet etching, dry etching, or mechanical removal after the process).

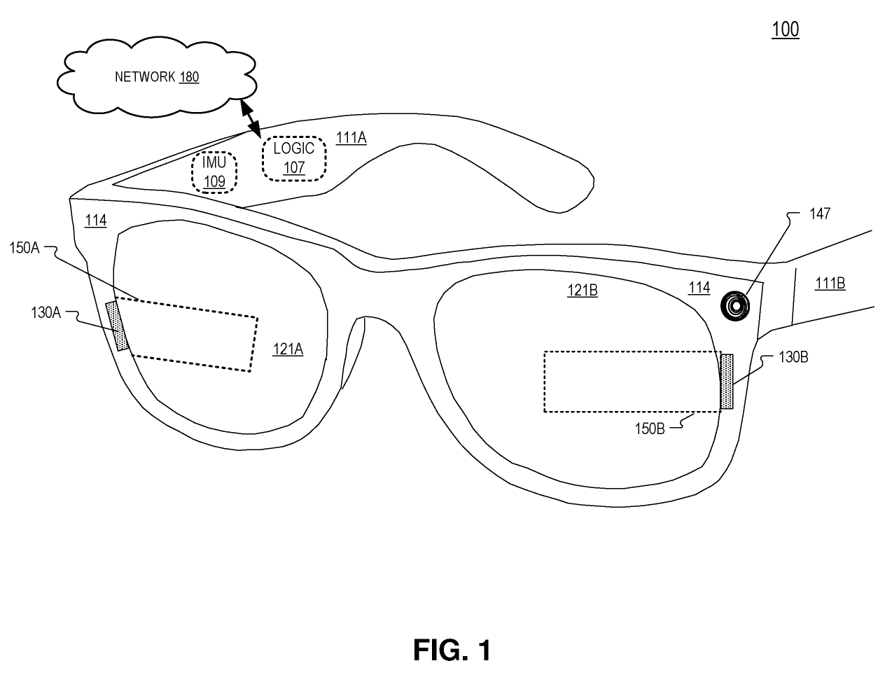

In an implementation of the disclosure, an image sensor includes a substrate, a semiconductor die, a mold material, and a micro-dam. The semiconductor die is connected atop the substrate by a wire bond. The semiconductor die includes a two-dimensional pixel array on a top surface of the semiconductor die. The mold material is deposited on the top surface of the semiconductor die to a mold height that exceeds a height of the wire bond. The micro-dam is disposed on the top surface of the semiconductor die between the two-dimensional pixel array and the mold material. The micro-dam is configured to prevent the mold material from reaching a semiconductor feature zone of the semiconductor die. The micro-dams in the disclosure may be an epoxy that includes a base material and a hardening agent. These and other embodiments are described in more detail in connection with FIGS. 1-14B.

FIG. 1 illustrates a head-mounted device 100 that includes one or more cameras 147 that may be exposed to an external environment, in accordance with aspects of the present disclosure. One or more cameras 147 is included in head-mounted device 100. An image sensor in camera(s) 147 may include the structures describe in the disclosure and be fabricated using the processes described herein. Camera 147 may be exposed to an external environment of the head-mounted device 100. Head-mounted device 100 includes frame 114 coupled to arms 111A and 111B. Lens assemblies 121A and 121B are mounted to frame 114. Lens assemblies 121A and 121B may include prescription lenses matched to a particular user of head-mounted device 100. The illustrated head-mounted device 100 is configured to be worn on or about a head of a wearer of head-mounted device 100.

In the head-mounted device 100 illustrated in FIG. 1, each lens assembly 121A/121B includes a waveguide 150A/150B to direct image light generated by displays 130A/130B to an eyebox area for viewing by a user of head-mounted device 100. Displays 130A/130B may include a beam-scanning display or a liquid crystal on silicon (LCOS) display for directing image light to a wearer of head-mounted device 100 to present virtual images, for example. Hence, head-mounted device 100 may be considered a head-mounted display (HMD) when a near-eye display is included in head-mounted device 100.

Lens assemblies 121A and 121B may appear transparent to a user to facilitate augmented reality or mixed reality to enable a user to view scene light from the environment around them while also receiving image light directed to their eye(s) by, for example, waveguides 150. Lens assemblies 121A and 121B may include two or more optical layers for different functionalities such as display, eye-tracking, and optical power. In some embodiments, image light from display 130A or 130B is only directed into one eye of the wearer of head-mounted device 100. In an embodiment, both displays 130A and 130B are used to direct image light into waveguides 150A and 150B, respectively. The implementations of the disclosure may also be used in head-mounted devices (e.g. smartglasses) that don’t necessarily include a display but are configured to be worn on or about a head of a wearer. Head-mounted device 100 is an example wearable that may include sensors, image sensors, MEMS devices, or displays that use the structures and fabrication methods disclosed herein.

Frame 114 and arms 111 may include supporting hardware of head-mounted device 100 such as processing logic 107, a wired and/or wireless data interface for sending and receiving data, graphic processors, and one or more memories for storing data and computer-executable instructions. Processing logic 107 may include circuitry, logic, instructions stored in a machine-readable storage medium, ASIC circuitry, FPGA circuitry, and/or one or more processors. In one embodiment, head-mounted device 100 may be configured to receive wired power. In one embodiment, head-mounted device 100 is configured to be powered by one or more batteries. In one embodiment, head-mounted device 100 may be configured to receive wired data including video data via a wired communication channel. In one embodiment, head-mounted device 100 is configured to receive wireless data including video data via a wireless communication channel. Processing logic 107 may be communicatively coupled to a network 180 to provide data to network 180 and/or access data within network 180. The communication channel between processing logic 107 and network 180 may be wired or wireless.

In FIG. 1, head-mounted device 100 includes an inertial measurement unit (IMU) 109 configured to generate motion signals. IMU 109 may be communicatively coupled to processing logic 107. Processing logic 107 may be configured to receive motion signals from IMU 109. IMU 109 may include gyroscopes to measure angular velocity, accelerometers to detect linear acceleration, and/or magnetometers to sense the magnetic field of the earth. All or a portion of the signals may be included in the motion data generated by IMU 109. IMU 109 may provide motion data to calculate position and attitude (orientation) of the head-mounted device 100 over time.

In the illustrated implementation of FIG. 1, head-mounted device 100 includes a camera 147. Camera 147 is illustrated as a front-facing camera in FIG. 1, although cameras described in the disclosure may be oriented to capture images from alternative perspectives. Head-mounted device 100 may include more than one camera that include the camera protection features described herein.

Camera 147 may include a lens assembly configured to focus image light to a complementary metal-oxide semiconductor (CMOS) image sensor, in some implementations. A near-infrared filter that receives a narrow-band near-infrared wavelength may be placed over the image sensor so it is sensitive to the narrow-band near-infrared wavelength while rejecting visible light and wavelengths outside the narrow-band, in some implementations.

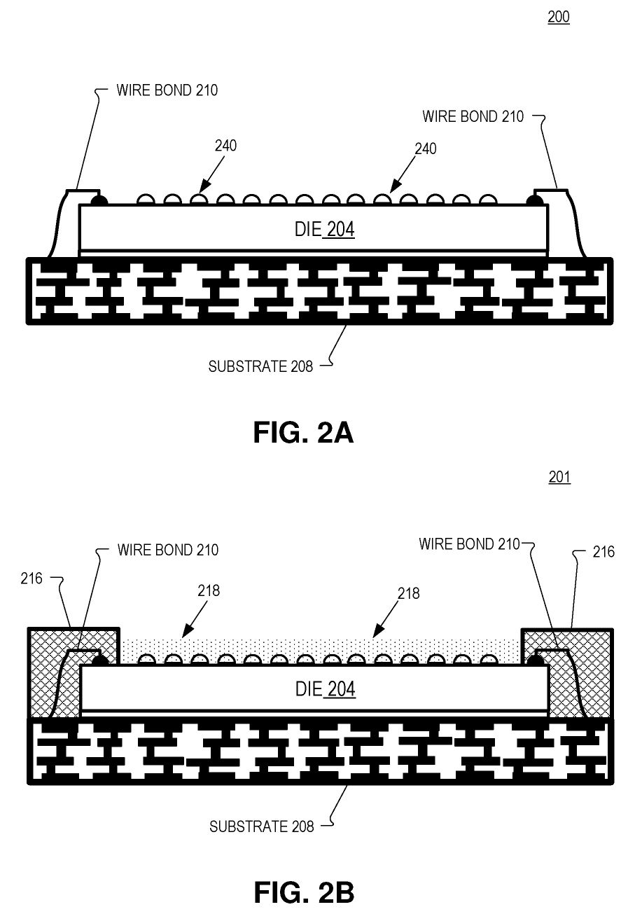

FIG. 2A illustrates an electronic package 200 structured according to an existing process. Electronic package 200 includes a substrate 208 and a semiconductor die 204. The semiconductor die 204 may be positioned atop a substrate 208 and wire bonds 210 may connect a top surface of the die 204 to a top surface of the substrate 208.

FIG. 2B illustrates electronic package 201 after a molding process that deposits mold material 216 to encapsulate wire bonds 210. Mold material 216 may include an adhesive. The mold material 216 may provide a structure that may mechanically support additional systems (e.g., an optical stack) above the one or more features of the electronic package 201 that are included in semiconductor die 204. However, the cavity molding process may cause contamination and/or mechanical damage 218 to the one or more features, resulting in significant yield losses. This yield loss increases time and costs in manufacturing sensor packages.

In the illustrations of FIGS. 2A-2B, microlenses 240 are included and the semiconductor die 204 includes an image pixel array. The array of microlenses 240 focus image light to image pixels in the image pixel array. While FIGS. 2A-2B illustrate an image sensor included in electronic package 201, the damage and contamination on semiconductor die 204 may also be present on other electronic packages such as display pixel arrays, sensors, and/or MEMS devices.

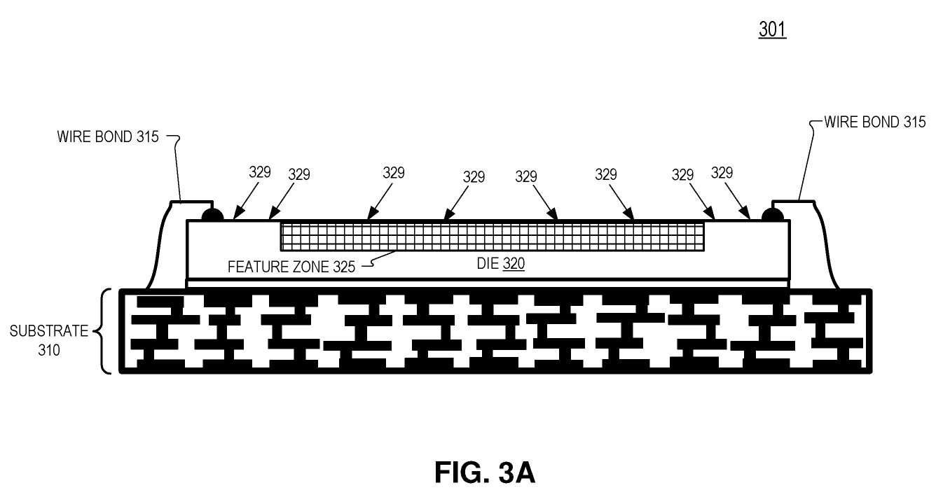

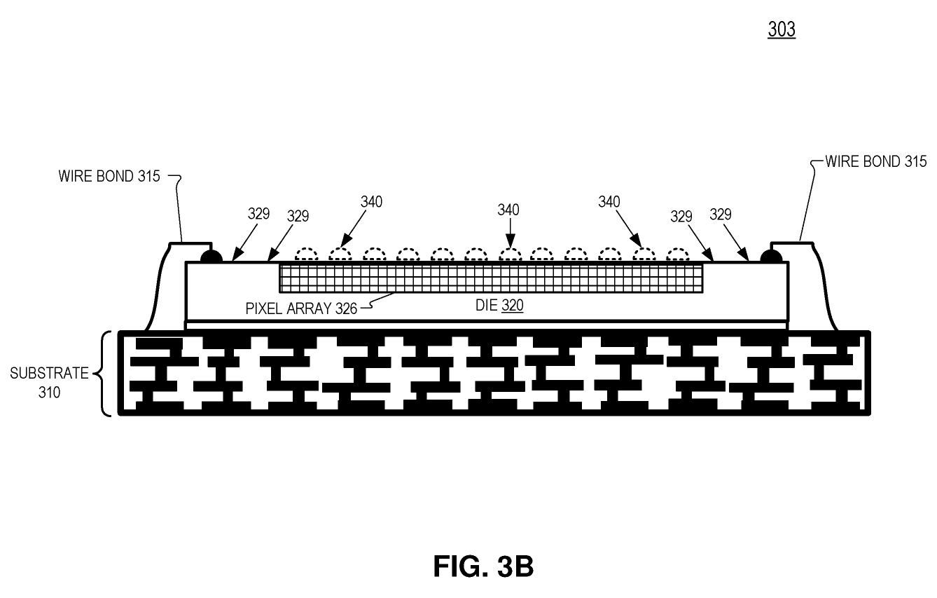

FIG. 3A illustrates an example electronic structure 301, in accordance with aspects of the disclosure. Example electronic structure 301 includes a semiconductor die 320 and a substrate 310. Substrate 310 may include electrical traces and insulators. Substrate 310 may include electronic pads for soldering electronic components to. Substrate 310 may include multiple layers of traces. Substrate 310 may include a printed circuit board. Substrate 310 may ensure mechanical support, electrical pathways, and heat dissipation for integrated circuits (ICs) and electronic devices. Materials like silicon, ceramics, laminate structures, and organic compounds may be used based on specific needs.

Semiconductor die 320 includes a feature zone 325. Feature zone 325 may include a two-dimensional image pixel array. Feature zone 325 may include a two-dimensional display pixel array. Feature zone 325 may include one or more sensors. Feature zone 325 may include one or more MEMS devices. Fabricating the different features into feature zone 325 may include doping the semiconductor and/or using existing CMOS processes to form transistors and other electronics into semiconductor die 320. The examples of this disclosure may reference fabricating an image sensor where feature zone 325 includes a two-dimensional image pixel array. However, even though an image sensor is referred to, the fabrication processes and structures may also apply to other devices such as display pixel arrays, sensors, and MEMS devices.

Semiconductor die 320 is connected atop the substrate 310 by one or more wire bonds 315. Semiconductor die 320 may include a two-dimensional image pixel array on a top surface 329 of the semiconductor die 320. The two-dimensional image pixel array may be within feature zone 325. Control circuits (e.g. readout circuits) that are configured to support an image capture using the two-dimensional image pixel array may be located in semiconductor die 320 outside feature zone 325.

FIG. 3B illustrates an example image sensor electronic device 303 that includes microlenses for focusing image light to an image pixel array, in accordance with implementations of the disclosure. Electronic device 303 is similar to electronic device 301. In electronic device 303, semiconductor feature zone 325 is a two-dimensional image pixel array 326 and microlenses 340 are also arranged in a two-dimensional array to focus image light to the two-dimensional image pixel array 326. In some implementations, microlenses 340 may have a height of 1.5 to 4 microns, for example. Microlenses 340 may be spherical, in some implementations.

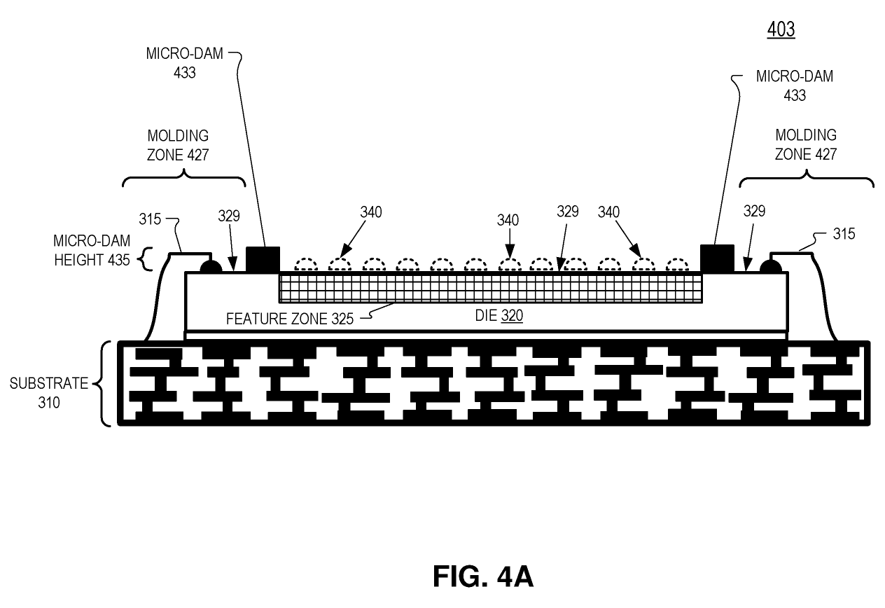

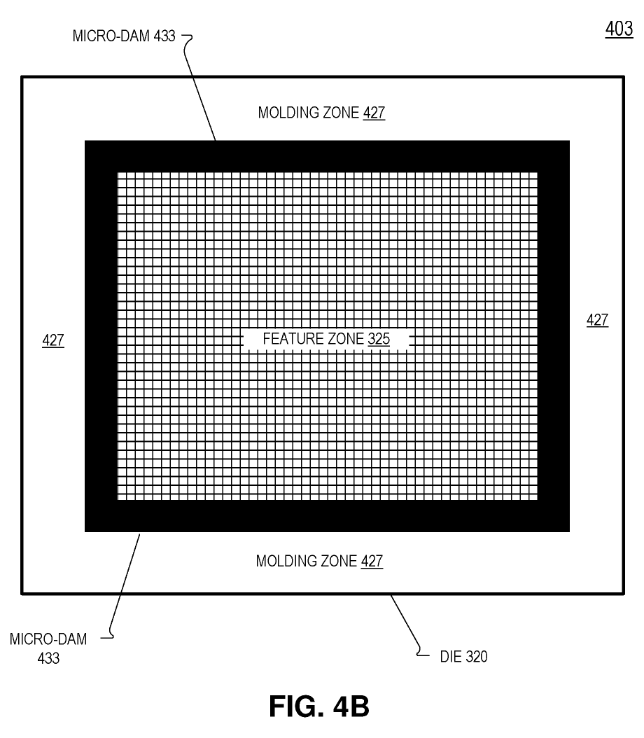

FIG. 4A illustrates electronic structure 403 that includes micro-dam 433 disposed on the top surface of semiconductor die 320, in accordance with aspects of the disclosure. Micro-dam 433 may be deposited on the top surface 329 of semiconductor die 320. Micro-dam 433 may be dispensed onto the top surface 329 of semiconductor die 320. Micro-dam 433 may include an adhesive material. Micro-dam 433 has a micro-dam height 435. Micro-dam height 435 may be taller than the microlenses 340. FIG. 4A also shows a molding zone 427 that a molding material may be placed in during a subsequent fabrication step.

FIG. 4B illustrates an overhead view of a portion of example electronic structure 403 that includes a micro-dam, in accordance with aspects of the disclosure. FIG. 4B illustrates micro-dam 433 disposed around the semiconductor feature zone 325. Semiconductor feature zone 325 may include a two-dimensional image pixel array 326, in some implementations. Micro-dam 433 may surround semiconductor feature zone 325, as illustrated. In some implementations, micro-dam 433 may not necessarily entirely surround semiconductor feature zone 325. FIG. 4B also shows a molding zone 427 that a molding material may be placed in during a subsequent fabrication step. Molding zone 427 is disposed around micro-dam 433. Micro-dam 433 is disposed on the top surface 329 of semiconductor die 320 between semiconductor feature zone 325 and molding zone 427.

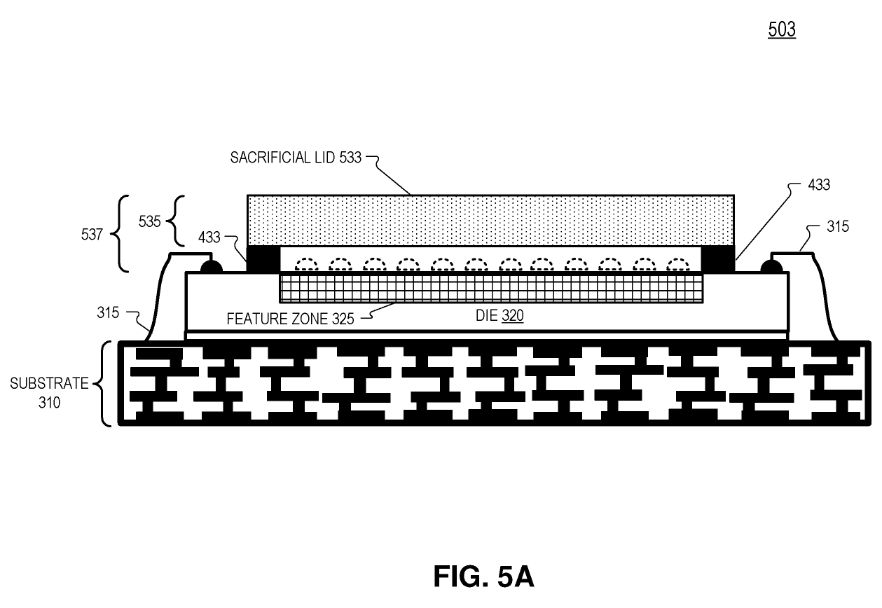

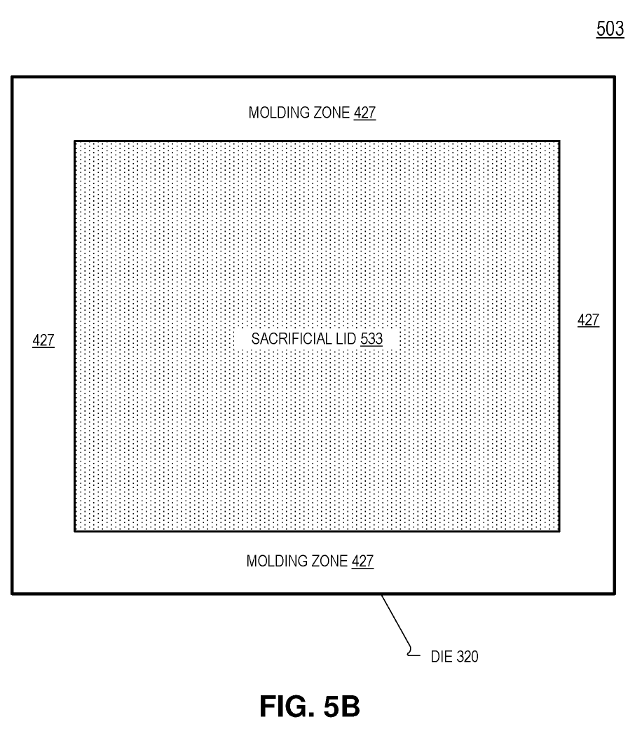

FIG. 5A illustrates electronic structure 503 that includes a sacrificial lid 533 relief structure disposed on micro-dam 433, in accordance with aspects of the disclosure. Sacrificial lid 533 is configured to cover and protect the top surface of semiconductor feature zone 325 (included in semiconductor die 320) from mechanical damage and/or contamination in subsequent fabrication steps. However, sacrificial lid 533 is also configured to be removed from the electronic structure 503 in a process step that uncovers the semiconductor feature zone 325. When electronic structure 503 is an image sensor and semiconductor feature zone 325 is a two-dimensional image pixel array, removing sacrificial lid 533 allows the two-dimensional image pixel array 326 to receive image light. Sacrificial lid 533 is configured to be removed from the image sensor in a process that uncovers the two-dimensional image pixel array to receive image light. When microlenses 340 are included, sacrificial lid 533 may also protect microlenses 340 from mechanical damage and/or contamination in subsequent fabrication steps.

FIG. 5A shows that sacrificial lid 533 has a lid thickness 535. Sacrificial lid 533 may contact micro-dam 433 without contacting the semiconductor feature zone 325 (e.g. two-dimensional image pixel array 326) to avoid contaminating and damaging the features in feature zone 325. In implementations, micro-dam 433 has a height 435 tall enough to support the sacrificial lid 533 to prevent the sacrificial lid 533 from contacting the microlenses 340. In the illustration of FIG. 5A, sacrificial lid 533 has a uniform thickness 535. In another implementation, the sacrificial lid is stepped and the sacrificial lid is thicker at outer regions that lie atop the micro-dam and thinner (e.g., but at least one-hundred microns thick) at inner regions that cover the one or more features. The reduced thickness of the sacrificial lid at the inner regions may reduce the time consumed in removing that portion of the sacrificial lid (e.g., by etching), thus reducing processing time and related costs.

Sacrificial lid 533 may include copper, aluminum, or polymer. In some implementations, sacrificial lid 533 has a lid thickness 535 measurement of at least one-hundred microns. Sacrificial lid 533 exhibits a height 537 measured from the top surface of the sacrificial lid 533 to the top surface 329 of the semiconductor die 320. In some implementations, lid height 537 is at least one-hundred microns. Micro-dam 433 may have a height 435 tall enough to support the sacrificial lid 533 to prevent the sacrificial lid 533 from contacting the microlenses 340, in some implementations.

FIG. 5B illustrates an overhead view of a portion of example electronic structure 503 that includes a sacrificial lid 533 covering semiconductor feature zone 325, in accordance with aspects of the disclosure. FIG. 5B illustrates sacrificial lid 533 disposed over micro-dam 433 and semiconductor feature zone 325. Molding zone 427 is disposed adjacent to sacrificial lid 533 in the overhead view.

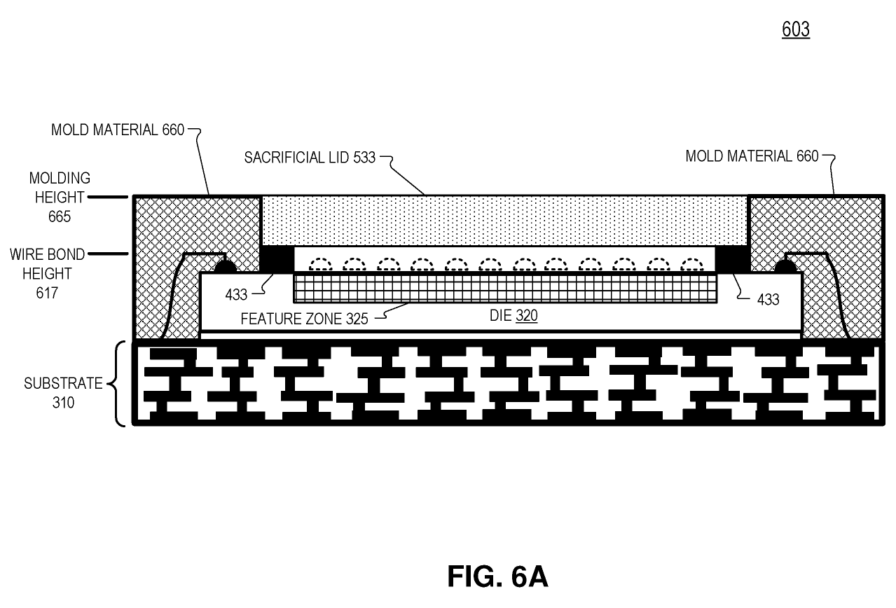

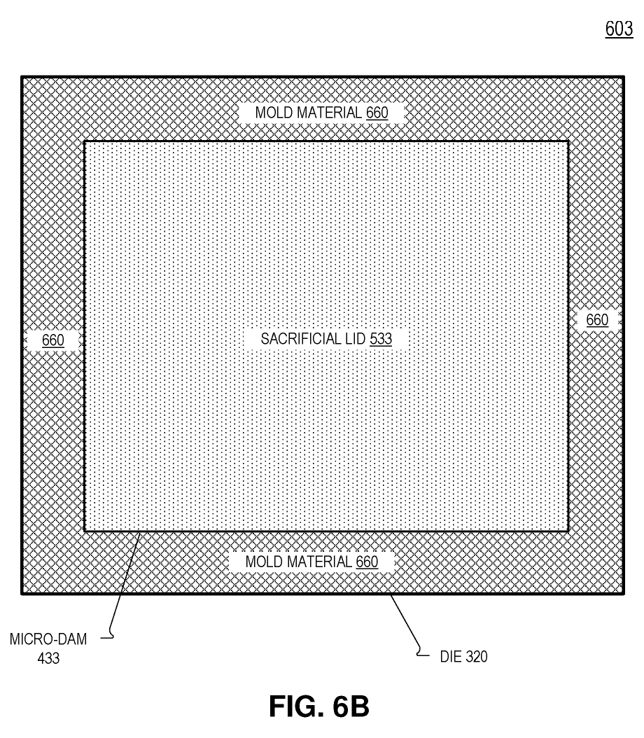

FIG. 6A illustrates electronic structure 603 that includes a mold material 660 deposited on the top surface 329 of semiconductor die 320, in accordance with aspects of the disclosure. Mold material 660 may be deposited on the top surface 329 of semiconductor die 320 to a molding height 665 that exceed a height 617 of the wire bond 315 to encapsulate the wire bond 315. Molding material 660 is also disposed on substrate 310, in FIG. 6A. The mold height 665 of the mold material 660 meets or exceeds a height of the sacrificial lid 533 in some implementations. In some implementations (not particularly illustrated) molding material covers sacrificial lid 533. Micro-dam 433 is disposed on the top surface 329 of semiconductor die 320 between the mold material 660 and semiconductor feature zone 325. Micro-dam 433 may be configured to support sacrificial lid 533 that covers a two-dimensional pixel array during the molding process that deposits the mold material 660.

FIG. 6B illustrates an overhead view of a portion of example electronic structure 603 that includes a molding material 660 disposed around sacrificial lid 533, in accordance with aspects of the disclosure. In some implementations, mold material 660 covers sacrificial lid 533.

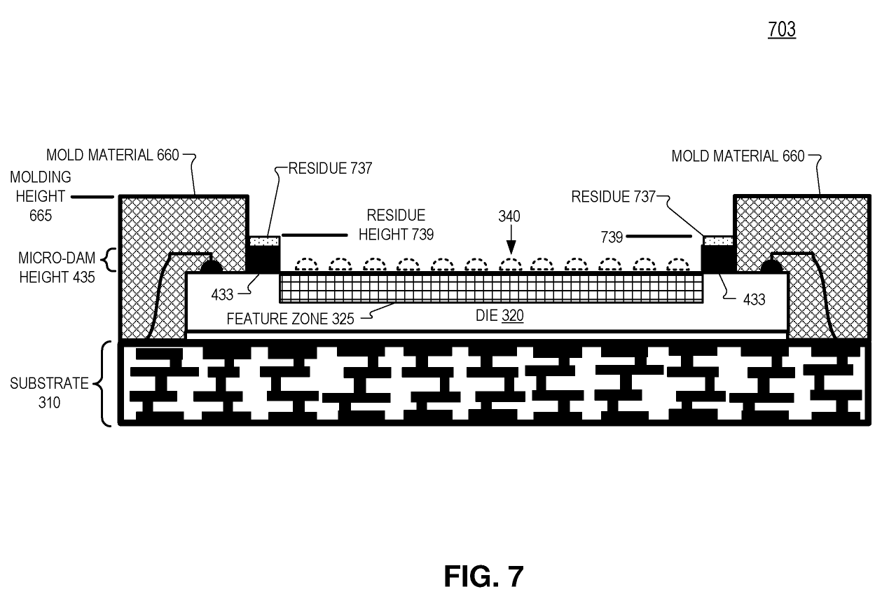

FIG. 7 illustrates electronic structure 703 after sacrificial lid 533 has been removed to uncover semiconductor feature zone 325, in accordance with aspects of the disclosure. FIG. 7 shows that in some implementations, a residual sacrificial lid material 737 may be left over from the removal of the sacrificial lid 533. Residual sacrificial lid material 737 is disposed over the micro-dam 433 between the mold material 660 and the semiconductor feature zone 325 which may include two-dimensional image pixel array 326 or other semiconductor feature. Residual sacrificial lid material 737 does not cover semiconductor feature zone 325, in FIG. 7. In the illustrated implementation, residual sacrificial lid material 737 has a height 739 that is less than mold height 665. FIG. 7 in combination with FIG. 5A illustrates that micro-dam 433 has a height 435 tall enough to have previously supported the sacrificial lid 533 to prevent the sacrificial lid 533 from contacting the microlenses 340.

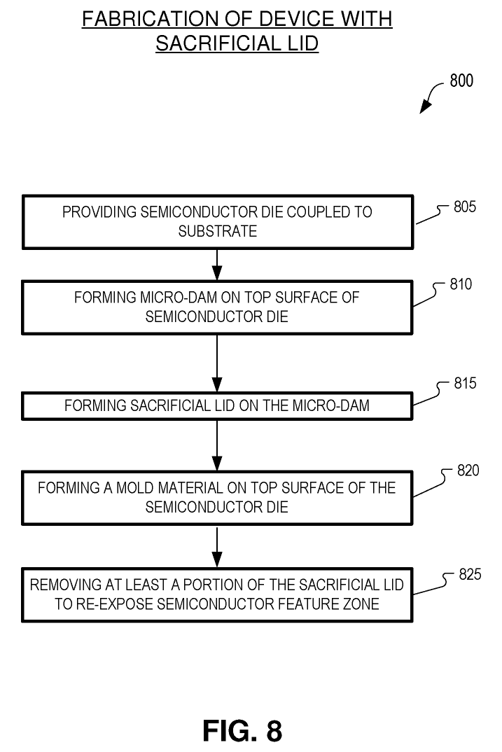

FIG. 8 illustrates an example process 800 of fabricating a device where the fabrication process includes a sacrificial lid, in accordance with aspects of the disclosure. The order in which some or all of the process blocks appear in process 800 should not be deemed limiting. Rather, one of ordinary skill in the art having the benefit of the present disclosure will understand that some of the process blocks may be executed in a variety of orders not illustrated, or even in parallel. In implementations, process block 825 may be performed subsequent to process block 820, process block 820 may be performed subsequent to process block 815, process block 815 may be performed subsequent to process block 810, and process block 810 may be performed subsequent to process block 805.

In process block 805, a semiconductor die coupled to a substrate is provided. The semiconductor die includes a semiconductor feature zone (e.g. zone 325) on a top surface of the semiconductor die. The substrate is electrically coupled to the semiconductor die by a wire bond.

In process block 810, a micro-dam is formed on the top surface of the semiconductor die and the micro-dam is disposed around the semiconductor feature zone. The micro-dam may include an adhesive material. The micro-dam (e.g. micro-dam 433) may have a height of at least four micrometers to ensure sufficient clearance features such as microlenses of an image pixel array of an image sensor.

In process block 815, a sacrificial lid is formed on the micro-dam. The sacrificial lid is covering up the semiconductor feature zone. The sacrificial lid 533 may include copper, aluminum, or polymer. The sacrificial lid may have a lid thickness of at least one-hundred microns. In an implementation, the sacrificial lid exhibits a height of at least one-hundred microns measured from a top surface of the sacrificial lid to the top surface of the semiconductor die. The sacrificial lid may be formed by sputtering a patch of material (e.g., aluminum).

In process block 820, a mold material is formed on the top surface of the semiconductor die that is outside of the micro-dam. The mold material is formed at a mold height that exceeds a height of the wire bond.

In process block 825, at least a portion of the sacrificial lid is removed to re-expose the semiconductor feature zone subsequent to forming the micro-dam, the sacrificial lid, and the mold material. The removal of the sacrificial lid may include removing one or more patch portions of the sacrificial lid. Removing the sacrificial lid may include chemical etching, wet etching, dry etching, or mechanical removal (e.g. mechanical polishing).

In an implementation of process 800, the semiconductor feature zone includes a two-dimensional image pixel array formed in the semiconductor die and microlenses configured to focus image light to image pixels in the two-dimensional image pixel array are disposed over the two-dimensional image pixel array. The micro-dam has a height tall enough to support the sacrificial lid to prevent the sacrificial lid from contacting the microlenses.

In an implementation of process 800, the semiconductor feature zone includes a two-dimensional display pixel array formed in the semiconductor die. In another implementation, the semiconductor feature zone includes a sensor formed in the semiconductor die.

Process 800 may include packaging the semiconductor device according to a wafer-level packaging process. In this context, configuring the sacrificial lid may include sputtering an aluminum patch atop the one or more semiconductor feature zone.

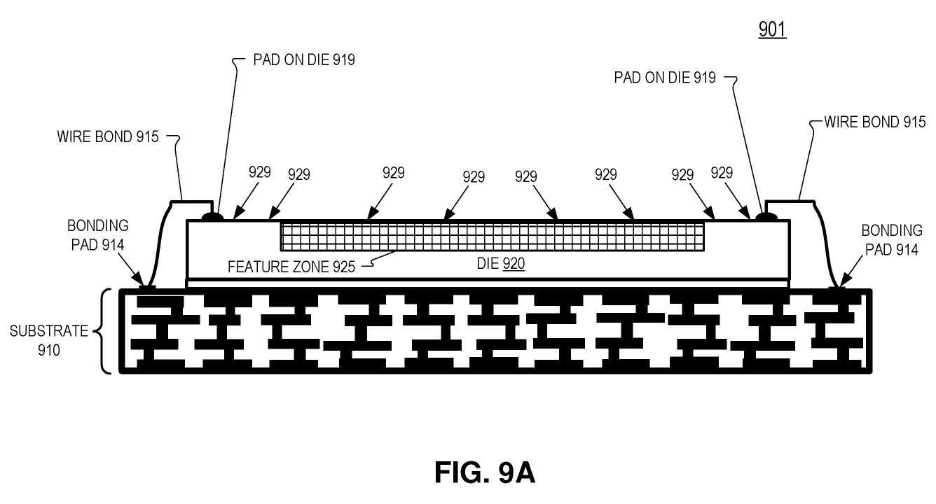

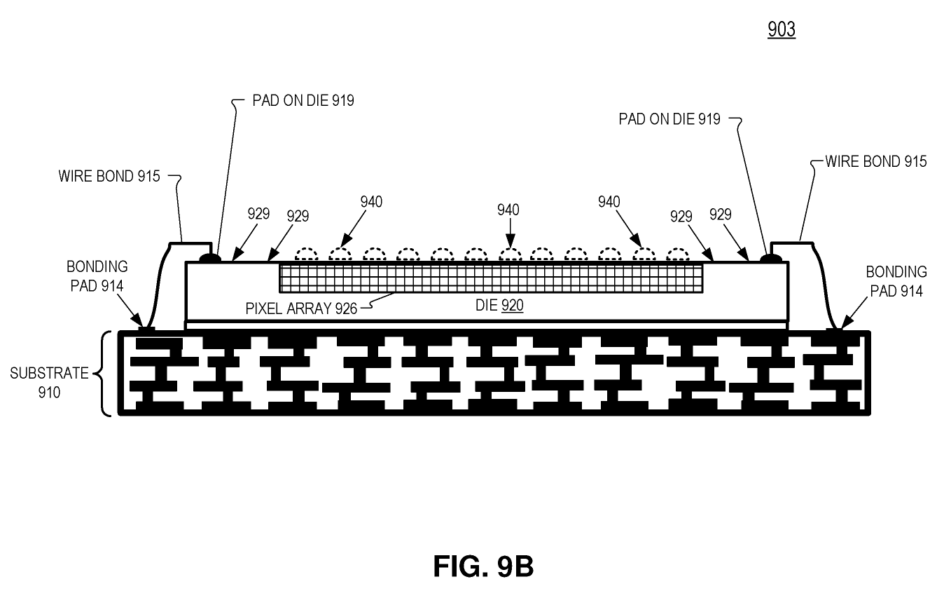

FIG. 9A illustrates an example electronic structure 901, in accordance with aspects of the disclosure. Example electronic structure 901 includes a semiconductor die 920 and a substrate 910. Substrate 910 may include electrical traces and insulators. Substrate 910 may include electronic pads for soldering electronic components to. Substrate 910 include bonding pad 914. Substrate 910 may include multiple layers of traces. Substrate 910 may include a printed circuit board. Substrate 910 may ensure mechanical support, electrical pathways, and heat dissipation for integrated circuits (ICs) and electronic devices. Materials like silicon, ceramics, laminate structures, and organic compounds may be used based on specific needs.

Semiconductor die 920 includes a feature zone 925. Feature zone 925 may include a two-dimensional image pixel array. Feature zone 925 may include a two-dimensional display pixel array. Feature zone 925 may include one or more sensors. Feature zone 925 may include one or more MEMS devices. Fabricating the different features into feature zone 925 may include doping the semiconductor and/or using existing CMOS processes to form transistors and other electronics into semiconductor die 920. The examples of this disclosure may reference fabricating an image sensor where feature zone 925 includes a two-dimensional image pixel array. However, even though an image sensor is referred to, the fabrication processes and structures may also apply to other devices such as display pixel arrays, sensors, and MEMS devices.

Semiconductor die 920 is connected atop the substrate 910 by one or more wire bonds 915. Pad-on-die 919 of wire bond 915 is located on semiconductor die 920. Semiconductor die 920 may include a two-dimensional image pixel array on a top surface 929 of the semiconductor die 920. The two-dimensional image pixel array may be within feature zone 925. Control circuits (e.g. readout circuits) that are configured to support an image capture using the two-dimensional image pixel array may be located in semiconductor die 920 outside feature zone 925.

FIG. 9B illustrates an example image sensor electronic device 903 that includes microlenses for focusing image light to an image pixel array, in accordance with implementations of the disclosure. Electronic device 903 is similar to electronic device 901. In electronic device 903, semiconductor feature zone 925 is a two-dimensional image pixel array 926 and microlenses 940 are also arranged in a two-dimensional array to focus image light to the two-dimensional image pixel array 926. In some implementations, microlenses 940 may have a height of 1.5 to 4 microns, for example. Microlenses 940 may be spherical, in some implementations.

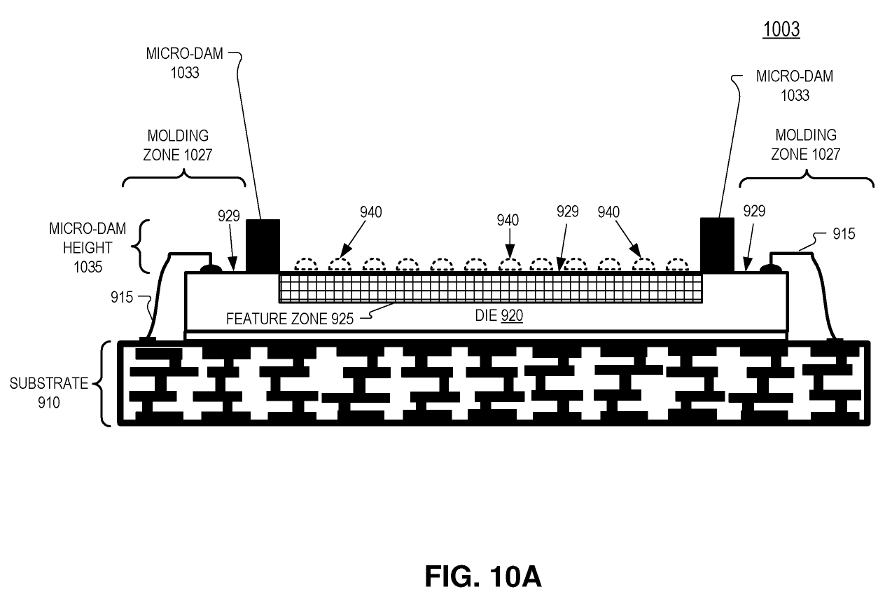

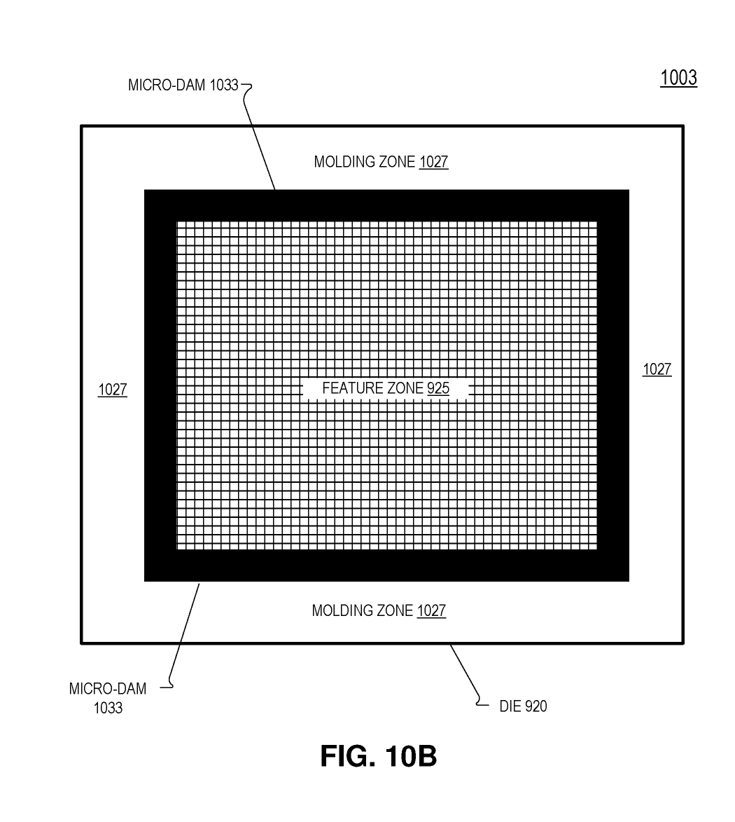

FIG. 10A illustrates electronic structure 1003 that includes micro-dam 1033 disposed on the top surface of semiconductor die 920, in accordance with aspects of the disclosure. Micro-dam 1033 may be deposited on the top surface 929 of semiconductor die 920. Micro-dam 1033 may be dispensed onto the top surface 929 of semiconductor die 920. Micro-dam 1033 may include an adhesive material. Micro-dam 1033 has a micro-dam height 1035. Micro-dam height 1035 may be taller than the microlenses 940. FIG. 10A also shows a molding zone 1027 that a molding material may be placed in during a subsequent fabrication step. Micro-dam 1033 is disposed on the top surface 929 of semiconductor die 920. Micro-dam 1033 is configured to prevent the mold material 1160 from reaching semiconductor feature zone 925 of semiconductor die 920.

FIG. 10B illustrates an overhead view of a portion of example electronic structure 1003 that includes a micro-dam, in accordance with aspects of the disclosure. FIG. 10B illustrates micro-dam 1033 disposed around the semiconductor feature zone 925. Semiconductor feature zone 925 may include a two-dimensional image pixel array 926, in some implementations. Micro-dam 1033 may surround semiconductor feature zone 925, as illustrated. In some implementations, micro-dam 1033 may not necessarily entirely surround semiconductor feature zone 925. FIG. 10B also shows a molding zone 1027 that a molding material may be placed in during a subsequent fabrication step. Molding zone 1027 is disposed around micro-dam 1033. Micro-dam 1033 is disposed on the top surface 929 of semiconductor die 920 between semiconductor feature zone 925 and molding zone 1027.

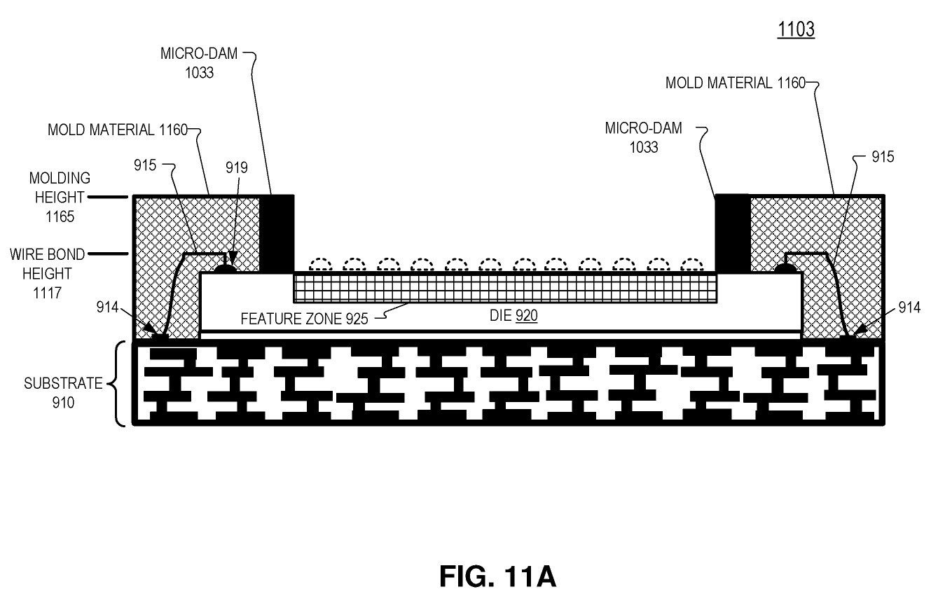

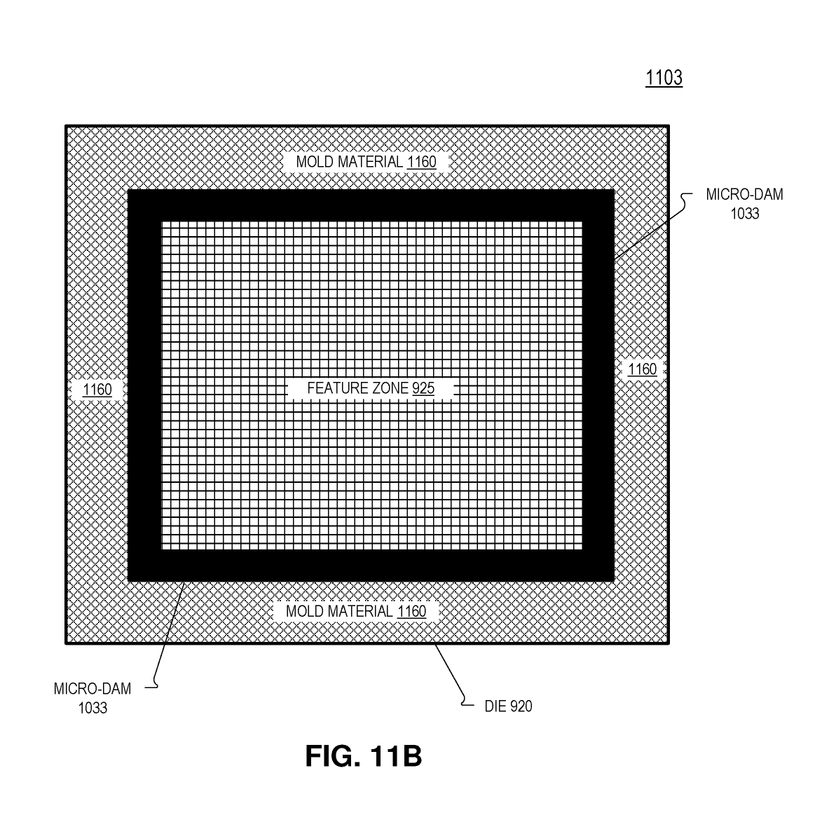

FIG. 11A illustrates electronic structure 1103 that includes mold material 1160 disposed next to micro-dam 1033, in accordance with aspects of the disclosure. Mold material 1160 is deposited to electronic structure 1003 of FIG. 10A and encapsulates pad-on-die 919 of wire bond 915 located on the semiconductor die 920. Mold material 1160 also encapsulates bonding pad 914 (on substrate 910) of wire bond 915. Micro-dam 1033 has a height tall enough to prevent the molding material 1160 from contacting microlenses 940. In an implementation, molding material 1160 includes a B-stage material that is a thermosetting resin. The thermosetting resin may have been partially cured to a stable, non-tacky state, allowing it to be easily handled and stored until it is fully cured under heat and pressure during a final assembly process.

Micro-dam 1033 is disposed on the top surface 929 of semiconductor die 920 between the two-dimensional pixel array 926 and the mold material 1160, in FIG. 11A. Mold material 1160 encapsulates pad-on-die 919 (of wire bond 915) located on semiconductor die 920 and mold material 110 also encapsulates bonding pad 914 (of wire bond 915) located on substrate 910. Mold material 1160 is deposited on the top surface 929 of semiconductor die 920 to a molding height 1165 that exceeds a height 1117 of the wire bond 915.

FIG. 11B illustrates an overhead view of a portion of example electronic structure 1103 that includes micro-dam 1033 arranged to prevent mold material 1160 from reaching a semiconductor features zone 925 of the semiconductor die 920.

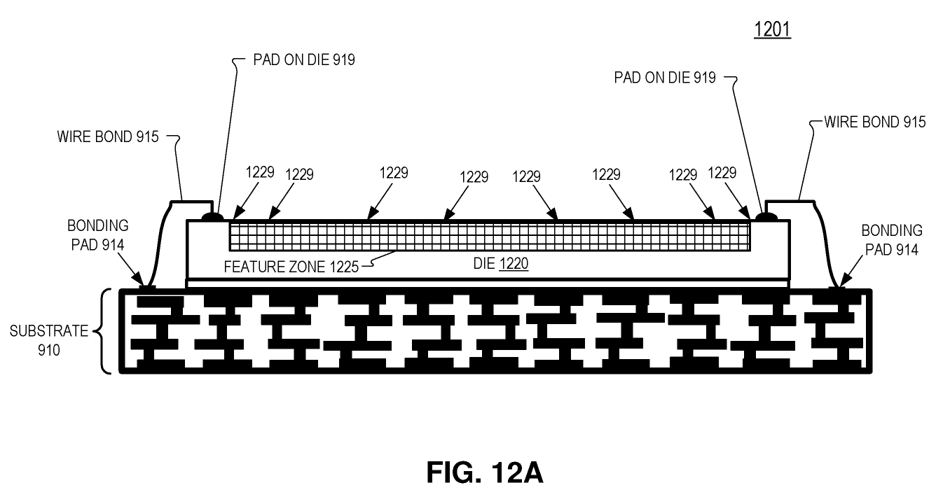

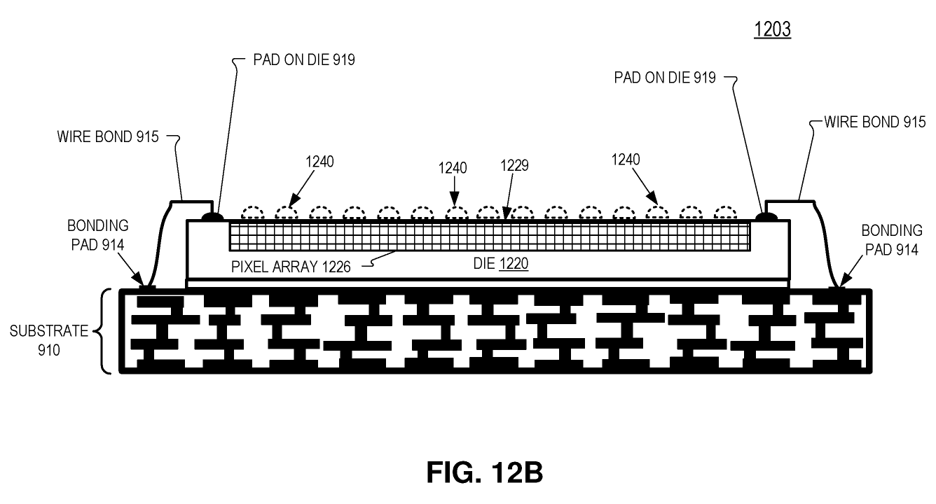

FIG. 12A illustrates an example electronic structure 1201, in accordance with aspects of the disclosure. Example electronic structure 1201 includes a semiconductor die 1220 and substrate 910. Semiconductor die 1220 includes a feature zone 1225. Feature zone 1225 may include a two-dimensional image pixel array. Feature zone 1225 may include a two-dimensional display pixel array. Feature zone 1225 may include one or more sensors. Feature zone 1225 may include one or more MEMS devices. Fabricating the different features into feature zone 1225 may include doping the semiconductor and/or using existing CMOS processes to form transistors and other electronics into semiconductor die 1220. The examples of this disclosure may reference fabricating an image sensor where feature zone 1225 includes a two-dimensional image pixel array. However, even though an image sensor is referred to, the fabrication processes and structures may also apply to other devices such as display pixel arrays, sensors, and MEMS devices.

Semiconductor die 1220 is connected atop the substrate 910 by one or more wire bonds 915. Pad-on-die 919 of wire bond 915 is located on semiconductor die 1220. Semiconductor die 1220 may include a two-dimensional image pixel array on a top surface 1229 of the semiconductor die 1220. The two-dimensional image pixel array may be within feature zone 1225. Control circuits (e.g. readout circuits) that are configured to support an image capture using the two-dimensional image pixel array may be located in semiconductor die 1220 outside feature zone 1225.

FIG. 12B illustrates an example image sensor electronic device 1203 that includes microlenses for focusing image light to an image pixel array, in accordance with implementations of the disclosure. Electronic device 1203 is similar to electronic device 1201. In electronic device 1203, semiconductor feature zone 1225 is a two-dimensional image pixel array 1226 and microlenses 1240 are also arranged in a two-dimensional array to focus image light to the two-dimensional image pixel array 1226. In some implementations, microlenses 1240 may have a height of 1.5 to 4 microns, for example. Microlenses 1240 may be spherical, in some implementations.

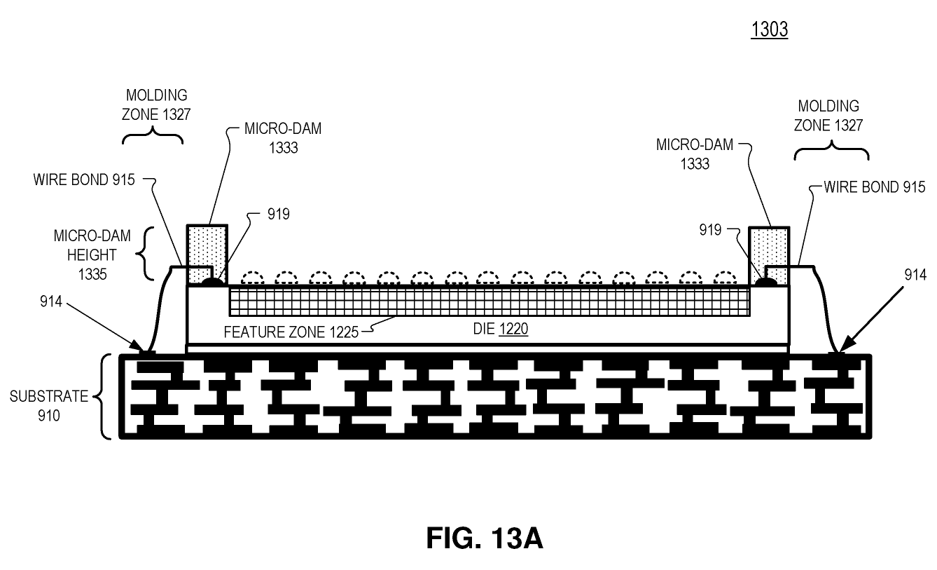

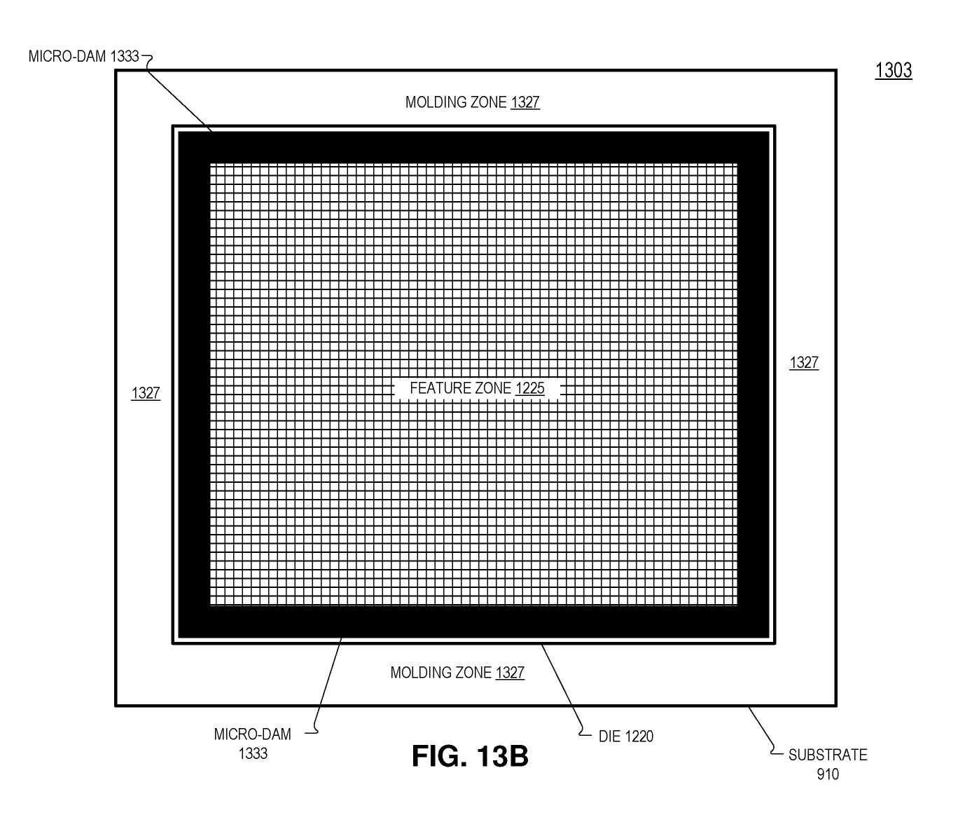

FIG. 13A illustrates electronic structure 1303 that includes micro-dam 1333 disposed on the top surface of semiconductor die 1220, in accordance with aspects of the disclosure. Micro-dam 1233 may be deposited on the top surface 1229 of semiconductor die 1220. Micro-dam 1333 may be dispensed onto the top surface 1229 of semiconductor die 1220. Micro-dam 1333 may include an adhesive material. Micro-dam 1333 has a micro-dam height 1335. Micro-dam height 1335 may be taller than the microlenses 1240. FIG. 13A also shows a molding zone 1327 that a molding material may be placed in during a subsequent fabrication step. Micro-dam 1333 is disposed on the top surface 229 of semiconductor die 220. Micro-dam 1333 is configured to prevent the mold material 1460 from reaching semiconductor feature zone 1225 of semiconductor die 1220.

FIG. 13B illustrates an overhead view of a portion of example electronic structure 1303 that includes a micro-dam, in accordance with aspects of the disclosure. FIG. 13B illustrates micro-dam 1333 disposed around the semiconductor feature zone 1225. Semiconductor feature zone 1225 may include a two-dimensional image pixel array 1226, in some implementations. Micro-dam 1333 may surround semiconductor feature zone 1225, as illustrated. In some implementations, micro-dam 1333 may not necessarily entirely surround semiconductor feature zone 1225. FIG. 13B also shows a molding zone 1327 that a molding material may be placed in during a subsequent fabrication step. Molding zone 1327 is disposed around micro-dam 1333. Micro-dam 1333 is disposed on the top surface 1229 of semiconductor die 1220 between semiconductor feature zone 1225 and molding zone 1327.

Notably, micro-dam 1333 encapsulates pad-on-die 919 in FIG. 13A. By forming the micro-dam 1333 on pad-on-die 919, the feature zone 1225 on semiconductor die 1220 can be larger than the feature zone 925 on semiconductor die 920 shown in FIG. 11A.

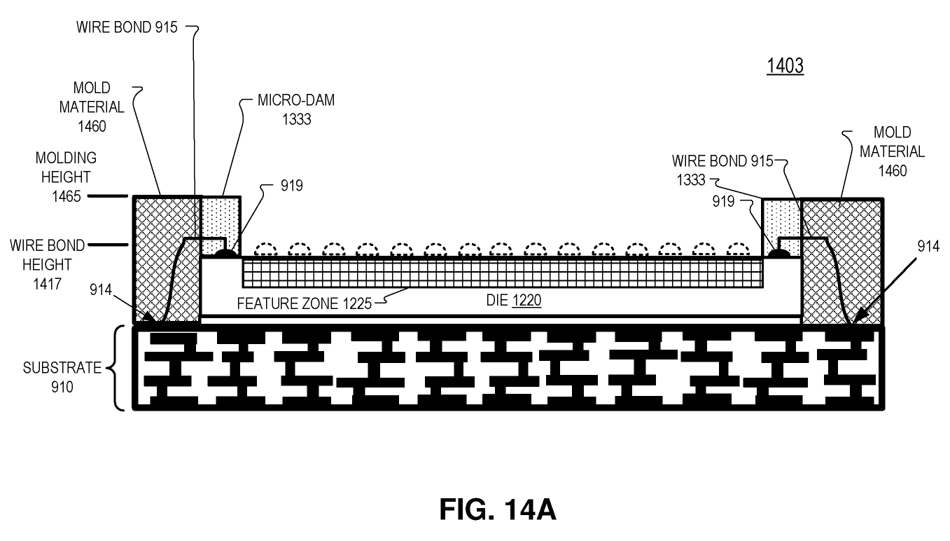

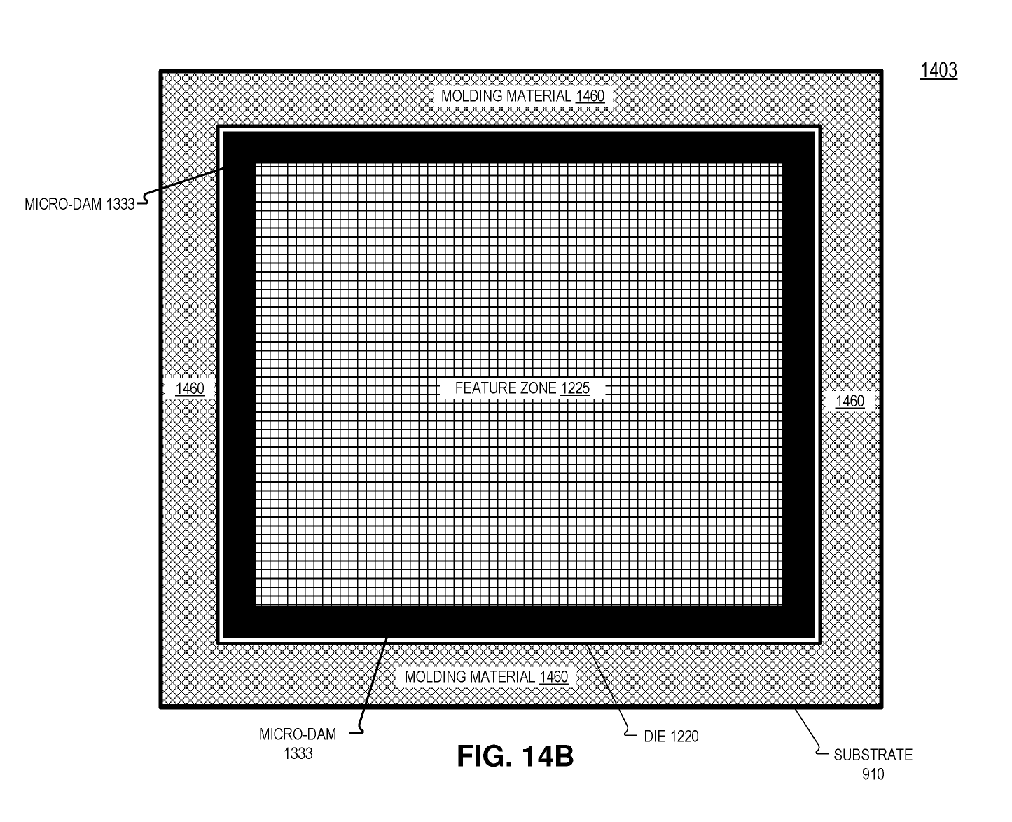

FIG. 14A illustrates electronic structure 1403 that includes mold material 1460 disposed next to micro-dam 1333, in accordance with aspects of the disclosure. Mold material 1460 is deposited to electronic structure 1303 of FIG. 13A and encapsulates bonding pad 914 (on substrate 910) of wire bond 915. However, mold material 1460 does not encapsulate pad-on-die 919, in FIG. 14A. Rather, micro-dam 1333 encapsulates pad-on-die 919. Micro-dam 1333 has a height 1335 tall enough to prevent the molding material 1460 from contacting microlenses 1240. In an implementation, molding material 1460 includes a B-stage material that is a thermosetting resin. The thermosetting resin may have been partially cured to a stable, non-tacky state, allowing it to be easily handled and stored until it is fully cured under heat and pressure during a final assembly process.

Micro-dam 1333 is disposed on the top surface 1229 of semiconductor die 1220 between the two-dimensional pixel array 1226 and the mold material 1360, in FIG. 14A. Mold material 1460 is formed on the top surface 1229 of semiconductor die 1220 to a mold height 1465 that exceeds a height 1417 of the wire bond 915.

FIG. 14B illustrates an overhead view of a portion of example electronic structure 1403 that includes micro-dam 1333 arranged to prevent mold material 1460 from reaching a semiconductor features zone 1225 of the semiconductor die 1220.

The process parameters and sequence of the steps described and/or illustrated herein are given by way of example only and can be varied as desired. For example, while the steps illustrated and/or described herein may be shown or discussed in a particular order, these steps do not necessarily need to be performed in the order illustrated or discussed. The various exemplary methods described and/or illustrated herein may also omit one or more of the steps described or illustrated herein or include additional steps in addition to those disclosed.

The preceding description has been provided to enable others skilled in the art to best utilize various aspects of the exemplary embodiments disclosed herein. This exemplary description is not intended to be exhaustive or to be limited to any precise form disclosed. Many modifications and variations are possible without departing from the spirit and scope of the present disclosure. The embodiments disclosed herein should be considered in all respects illustrative and not restrictive. Reference should be made to any claims appended hereto and their equivalents in determining the scope of the present disclosure.

Unless otherwise noted, the terms “connected to” and “coupled to”, as used in the specification and/or claims, are to be construed as permitting both direct and indirect (i.e., via other elements or components) connection. In addition, the terms “a” or “an,” as used in the specification and/or claims, are to be construed as meaning “at least one of.” Finally, for ease of use, the terms “including” and “having”, as used in the specification and/or claims, are interchangeable with and have the same meaning as the word “comprising.”

The term “processing logic” (e.g. processing logic 107) in this disclosure may include one or more processors, microprocessors, multi-core processors, Application-specific integrated circuits (ASIC), and/or Field Programmable Gate Arrays (FPGAs) to execute operations disclosed herein. In some embodiments, memories (not illustrated) are integrated into the processing logic to store instructions to execute operations and/or store data. Processing logic may also include analog or digital circuitry to perform the operations in accordance with embodiments of the disclosure.

A “memory” or “memories” described in this disclosure may include one or more volatile or non-volatile memory architectures. The “memory” or “memories” may be removable and non-removable media implemented in any method or technology for storage of information such as computer-readable instructions, data structures, program modules, or other data. Example memory technologies may include RAM, ROM, EEPROM, flash memory, CD-ROM, digital versatile disks (DVD), high-definition multimedia/data storage disks, or other optical storage, magnetic cassettes, magnetic tape, magnetic disk storage or other magnetic storage devices, or any other non-transmission medium that can be used to store information for access by a computing device.

Networks may include any network or network system such as, but not limited to, the following: a peer-to-peer network; a Local Area Network (LAN); a Wide Area Network (WAN); a public network, such as the Internet; a private network; a cellular network; a wireless network; a wired network; a wireless and wired combination network; and a satellite network. Communication channels may include or be routed through one or more wired or wireless communication utilizing IEEE 802.11 protocols, short-range wireless protocols, SPI (Serial Peripheral Interface), I²C (Inter-Integrated Circuit), USB (Universal Serial Port), CAN (Controller Area Network), cellular data protocols (e.g. 3G, 4G, LTE, 5G), optical communication networks, Internet Service Providers (ISPs), a peer-to-peer network, a Local Area Network (LAN), a Wide Area Network (WAN), a public network (e.g. “the Internet”), a private network, a satellite network, or otherwise.

A computing device may include a desktop computer, a laptop computer, a tablet, a phablet, a smartphone, a feature phone, a server computer, or otherwise. A server computer may be located remotely in a data center or be stored locally.

The processes explained above are described in terms of computer software and hardware. The techniques described may constitute machine-executable instructions embodied within a tangible or non-transitory machine (e.g., computer) readable storage medium, that when executed by a machine will cause the machine to perform the operations described. Additionally, the processes may be embodied within hardware, such as an application specific integrated circuit (“ASIC”) or otherwise.

The above description of illustrated embodiments of the invention, including what is described in the Abstract, is not intended to be exhaustive or to limit the invention to the precise forms disclosed. While specific embodiments of, and examples for, the invention are described herein for illustrative purposes, various modifications are possible within the scope of the invention, as those skilled in the relevant art will recognize.

These modifications can be made to the invention in light of the above detailed description. The terms used in the following claims should not be construed to limit the invention to the specific embodiments disclosed in the specification. Rather, the scope of the invention is to be determined entirely by the following claims, which are to be construed in accordance with established doctrines of claim interpretation.

What is claimed is:

1. An image sensor comprising:
a substrate;
a semiconductor die connected atop the substrate by a wire bond, wherein the semiconductor die includes a two-dimensional pixel array on a top surface of the semiconductor die;
a mold material deposited on the top surface of the semiconductor die to a mold height that exceeds a height of the wire bond; and
a micro-dam disposed on the top surface of the semiconductor die between the two-dimensional pixel array and the mold material, wherein the micro-dam is configured to prevent the mold material from reaching a semiconductor feature zone of the semiconductor die.

2. The image sensor of claim 1, wherein the micro-dam encapsulates a pad-on-die of the wire bond located on the semiconductor die, and wherein the mold material encapsulates a bonding pad of the wire bond located on the substrate.

3. The image sensor of claim 1, wherein the mold material encapsulates a pad-on-die of the wire bond located on the semiconductor die and encapsulates a bonding pad of the wire bond located on the substrate.

4. The image sensor of claim 1 further comprising:
microlenses configured to focus image light to image pixels in the two-dimensional pixel array, wherein the micro-dam has a height tall enough to prevent the molding material from contacting the microlenses.

5. The image sensor of claim 1, wherein the micro-dam includes an adhesive material.

6. The image sensor of claim 1, wherein the molding material includes a B-stage material that is a thermosetting resin.

7. An image sensor comprising:
a substrate;
a semiconductor die connected atop the substrate by a wire bond, wherein the semiconductor die includes a two-dimensional image pixel array on a top surface of the semiconductor die;
a micro-dam disposed on the top surface of the semiconductor die, wherein the micro-dam is disposed around the two-dimensional image pixel array; and
a sacrificial lid disposed on the micro-dam and covering the two-dimensional image pixel array from a molding process for encapsulating the wire bond, wherein the sacrificial lid is configured to be removed from the image sensor in a process that uncovers the two-dimensional image pixel array to receive image light.

8. The image sensor of claim 7, wherein the sacrificial lid contacts the micro-dam without contacting the two-dimensional image pixel array to avoid contaminating and damaging the two-dimensional image pixel array.

9. The image sensor of claim 7, wherein the micro-dam includes an adhesive material.

10. The image sensor of claim 7, a mold material deposited on the top surface of the semiconductor die to a mold height that exceeds a wire bond height of the wire bond to encapsulate the wire bond, wherein the mold height of the mold material meets or exceeds a height of the sacrificial lid, and wherein the micro-dam is disposed on the top surface of the semiconductor die between the mold material and the two-dimensional image pixel array.

11. The image sensor of claim 7 further comprising:
microlenses configured to focus image light to image pixels in the two-dimensional image pixel array, wherein the micro-dam has a height tall enough to support the sacrificial lid to prevent the sacrificial lid from contacting the microlenses.

12. The image sensor of claim 7, wherein a mold height of the mold material meets
or exceeds a height of the sacrificial lid.

13. The image sensor of claim 7, wherein the sacrificial lid includes copper.

14. The image sensor of claim 7, wherein the sacrificial lid includes aluminum.

15. The image sensor of claim 7, wherein the sacrificial lid includes a polymer.

16. The image sensor of claim 7, wherein the sacrificial lid exhibits a height of at
least one-hundred microns measured from a top surface of the sacrificial lid to the top surface of the semiconductor die.

17. An image sensor comprising:
a substrate;
a semiconductor die connected atop the substrate by a wire bond, wherein the semiconductor die includes a two-dimensional pixel array on a top surface of the semiconductor die;
a mold material deposited on the top surface of the semiconductor die to a mold height that exceeds a height of the wire bond; and
a micro-dam disposed on the top surface of the semiconductor die between the two-dimensional pixel array and the mold material, the micro-dam configured to have previously supported a sacrificial lid that covered the two-dimensional pixel array during a molding process that deposited the mold material.

18. The image sensor of claim 17 further comprising:
microlenses configured to focus image light to image pixels in the two-dimensional pixel array, wherein the micro-dam has a height tall enough to have previously supported the sacrificial lid to prevent the sacrificial lid from contacting the microlenses.

19. The image sensor of claim 17 further comprising:
residual sacrificial lid material disposed over the micro-dam between the mold material and the two-dimensional pixel array, wherein the residual sacrificial lid material does not cover the two-dimensional pixel array, and wherein the residual sacrificial lid material has a height that is less than a mold height of the mold material.

20. The image sensor of claim 17, wherein the micro-dam includes an adhesive material.
